(19) United States
(12) Patent Application Publication
(10) Pub. No.: US 2007/0045777 A1
(43) Pub. Date: Mar. 1, 2007

(54) Micronized semiconductor nanocrystal complexes and methods of making and using same

(76) Inventors: Jennifer Gillies, Petersburg, NY (US); Margaret Hines, Troy, NY (US)

Correspondence Address: KENYON & KENYON LLP, 1500 K STREET N.W., SUITE 700, WASHINGTON, DC, 20005, US

(21) Appl. No.: 11/175,196

(22) Filed: Jul. 7, 2005

Related U.S. Application Data
(60) Provisional application No. 60/585,942, filed on Jul. 8, 2004.

(51) Int. Cl. H01L 29/12; H01L 31/0256

(52) U.S. Cl. 257/613

(57) ABSTRACT

A micronized semiconductor nanocrystal complex including a plurality of semiconductor nanocrystals embedded in a first matrix material wherein the first matrix material is a micronized polymer. The micronized semiconductor nanocrystal complex can be used in or include inks, paints, dyes, LEDs, taggants, tracers and cosmetics. The present application further provides methods of making micronized semiconductor nanocrystal complexes.

### CROSS-REFERENCE TO RELATED APPLICATIONS

The present application claims priority to U.S. Provisional Application No. 60/585,942, filed Jul. 8, 2004, which is incorporated by reference herein.

### FIELD OF THE INVENTION

The present invention relates generally to micronized semiconductor nanocrystal complexes, methods of making micronized semiconductor nanocrystal complexes and to applications for micronized semiconductor nanocrystal complexes.

### BACKGROUND OF THE INVENTION

Semiconductor nanocrystals are typically tiny crystals of II-VI, III-V, IV-VI materials that have a diameter between 1 nanometer (nm) and 20 nm. In the strong confinement limit, the physical diameter of the nanocrystal is smaller than the bulk excitation Bohr radius causing quantum confinement effects to predominate. In this regime, the nanocrystal is a 0-dimensional system that has both quantized density and energy of electronic states where the actual energy and energy differences between electronic states are a function of both the nanocrystal composition and physical size. Larger nanocrystals have more closely spaced energy states and smaller nanocrystals have the reverse. Because interaction of light and matter is determined by the density and energy of electronic states, many of the optical and electric properties of nanocrystals can be tuned or altered simply by changing the nanocrystal geometry (i.e. physical size).

Single nanocrystals or monodisperse populations of nanocrystals exhibit unique optical properties that are size tunable. Both the onset of absorption and the photoluminescent wavelength are a function of nanocrystal size and composition. The nanocrystals will absorb all wavelengths shorter than the absorption onset, however, photoluminescence will always occur at the absorption onset. The bandwidth of the photoluminescent spectra is due to both homogeneous and inhomogeneous broadening mechanisms. Homogeneous mechanisms include temperature dependent Doppler broadening and broadening due to the Heisenburg uncertainty principle, while inhomogeneous broadening is due to the size distribution of the nanocrystals. The narrower the size distribution of the nanocrystals, the narrower the full-width half max (FWHM) of the resultant photoluminescent spectra. In 1991, Brus wrote a paper reviewing the theoretical and experimental research conducted on colloidally grown semiconductor nanocrystals, such as cadmium selenide (CdSe) in particular. (Brus L., Quantum Crystallites and Nonlinear Optics, Applied Physics A, 53 (1991), which is incorporated by reference herein). That research, precipitated in the early 1980's by the likes of Efros, Ekimov, and Brus himself, greatly accelerated by the end of the 1980's as demonstrated by the increase in the number of papers concerning colloidally grown semiconductor nanocrystals.

Quantum yield (i.e. the percent of absorbed photons that are reemitted as photons) is influenced largely by the surface quality of the nanocrystal. Photoexcited charge carriers will emit light upon direct recombination but will give up the excitation energy as heat if photon or defect mediated recombination paths are prevalent. Because the nanocrystal may have a large surface area to volume ratio, dislocations present on the surface or adsorbed surface molecules having a significant potential difference from the nanocrystal itself will tend to trap excited state carriers and prevent radiactive recombination and thus reduce quantum yield. It has been shown that quantum yield can be increased by removing surface defects and separating adsorbed surface molecules from the nanocrystal by adding a shell of a semiconductor with a wider bulk bandgap than that of the core semiconductor.

Inorganic colloids have been studied for over a century ever since Michael Faraday's production of gold sols in 1857. Rossetti and Brus began work on semiconductor colloids in 1982 by preparing and studying the luminescent properties of colloids consisting of II-VI semiconductors, namely cadmium sulfide (CdS). (Rossetti, R.; Brus L., Electron-Hole Recombination Emission as a Probe of Surface Chemistry in Aqueous CdS Colloids, J. Phys. Chem., 86, 172 (1982), which is incorporated by reference herein. In that paper, they describe the preparation and resultant optical properties of CdS colloids, where the mean diameter of the suspended particles is greater than 20 nm. Because the sizes of the particles were greater than the exaction Bohr radius, quantum confinement effects that result in the blue shifting of the fluorescence peak was not observed. However, fluorescence at the bulk bandedge energies were observed and had a FWHM of 50-60 nm.

CdS colloids exhibiting quantum confinement effects (blue shifted maxima in the absorption spectra) were being prepared since 1984. (Fotjik A., Henglein A., Ber. Bunsenges. Phys. Chem., 88, (1984); Fischer C., Fotjik A., Henglein A., Ber. Bunsenges. Phys. Chem., (1986)). In 1987, Spanhel and Henglein prepared CdS colloids having mean particle diameters between 4 and 6nm. (Spanhel L., Henglein A., Photochemistry of Colloidal Semiconductors, Surface Modification and Stability of Strong Luminescing CdS Particles, Am. Chem. Soc., 109 (1987), which is incorporated by reference herein). The colloids demonstrated quantum confinement effects including the observation of size dependent absorption maxima (first exciton peaks) as well as size dependent fluorescent spectra. The colloids were prepared by bubbling a sulphur containing gas (H₂S) through an alkaline solution containing dissolved cadmium ions. The size and resultant color (of the fluorescence) of the resultant nanocrystals were dependent upon the pH of the solution. The colloids were further modified or “activated” by the addition of cadmium hydroxide to the solution that coated the suspended nanocrystals. The resultant core-shell nanocrystals demonstrated that the quantum yield of the photoluminescence was increased from under 1% to well over 50% with a FWHM of the photoluminescent spectra under 50 nm for some of the preparations.

Kortan and Brus developed a method for creating CdSe coated zinc sulphide (ZnS) nanocrystals and the opposite, zinc sulphide coated cadmium selenide nanocrystals. (Kortan R., Brus L., Nucleation and Growth of CdSe on ZnS Quantum Crystallite Seeds, and Vice Versa, in Inverse Micelle Media, J. Am. Chem. Soc., 112 (1990), which is incorporated by reference herein). The preparation grew ZnS on CdSe “seeds” using a organometallic precursor-based reverse micelle technique and kept them in solution via an organic capping layer (thiol phenol). The CdSe core nanocrystals had diameters between 3.5 and 4 nm and demonstrated quantum confinement effects including observable exciton absorption peaks and blue shifted photoluminescence. Using another preparation, CdSe cores were coated by a 0.4 nm layer of ZnS. The photoluminescence spectra of the resultant core-shell nanocrystals indicates a peak fluorescence at 530 nm with an approximate 40-45 nm FWHM.

Murray and Bawendi developed an organometallic preparation capable of making CdSe, CdS, and CdTe nanocrystals. (Murray C., Norris D., Bawendi M., Synthesis and Characterization of Nearly Monodisperse CdE (E=S, Se, Te) Semiconductor Nanocrystallites, J. Am. Chem. Soc., 115, (1993), which is incorporated by reference herein). This work, based on the earlier works of Brus, Henglein, Peyghambarian, allowed for the growth of nanocrystals having a diameter between 1.2 nm and 11.5 nm and with a narrow size distribution (<5%). The synthesis involved a homogeneous nucleation step followed by a growth step. The nucleation step is initiated by the injection of an organometallic cadmium precursor (dimethyl cadmium) with a selenium precursor (TOPSe-TriOctylPhosphine Selenium) into a heated bath containing coordinating ligands (TOPO-TriOctylPhosphineOxide). The precursors disassociate in the solvent, causing the cadmium and selenium to combine to form a growing nanocrystal. The TOPO coordinates with the nanocrystal to moderate and control the growth. The resultant nanocrystal solution showed an approximate 10% size distribution, however, by titrating the solution with methanol the larger nanocrystals could be selectively precipitated from the solution thereby reducing the overall size distribution. After size selective precipitation, the resultant nanocrystals in solution were monodisperse (capable of reaching a 5% size distribution) but were slightly prolate (i.e. nonspherical having an aspect ratio between 1.1 and 1.3). The photoluminescence spectra show a FWHM of approximately 30-35 nm and a quantum yield of approximately 9.6%.

Katari and Alivisatos slightly modified the Murray preparation to make CdSe nanocrystals. (Katari J., Alivisatos A., X-ray Photoelectron Spectroscopy of CdSe Nanocrystals with Applications to Studies of the Nanocrystal Surface, J. Phys. Chem., 98 (1994), which is incorporated by reference herein). They found that by substituting the selenium precursor TOPSe with TBPSe (TriButylPhosphineSelenide), nanocrystals were produced that were monodisperse without size selective precipitation, were crystalline, and spherical. The nanocrystals were size tunable from 1.8 nm to 6.7 nm in diameter and had an exciton peak position ranging from 1.9-2.5 eV (corresponding to 635-496 nm wavelength). Like the Murray paper, TOPO was used as the coordinating ligand.

Hines and Guyot-Sionest developed a method for synthesizing a ZnS shell around a CdSe core nanocrystal. (Hines et al., “Synthesis and Characterization of strongly Luminescing ZnS capped CdSe Nanocrystals”; J. Phys. Chem., 100:468-471 (1996), which is incorporated by reference herein). The CdSe cores, having a monodisperse distribution between 2.7 nm and 3.0 nm (i.e. 5% size distribution with average nanocrystal diameter being 2.85 nm), were produced using the Katari and Alivisatos variation of the Murray synthesis. The photoluminescence spectra of the core shows a FWHM of approximately 30 nm with a peak at approximately 540 nm. The core CdSe nanocrystals were separated, purified, and resuspended in a TOPO solvent. The solution was heated and injected with zinc and sulphur precursors (dimethyl zinc and (TMS)₂S) to form a ZnS shell around the CdSe cores. The resultant shells were 0.6±0.3 nm thick, corresponding to 1-3 monolayers. The photoluminescence of the core-shell nanocrystals had a peak at 545 nm, FWHM of 40 nm, and a quantum yield of 50%.

Many of the above identified articles describe methods of making luminescent semiconductor nanocrystals. However, in order for nanocrystals to be used for many applications it is often desirable to have the nanocrystals placed in polymers, sol-gels, epoxies, thin films or other matrix materials. Some such applications include security applications, inks, paints, dyes, taggants and lighting applications. Although it has been shown that semiconductor nanocrystals may be placed in some of these matrix materials, often the semiconductor nanocrystals are either unable to be dispersed into these materials, i.e., they quench, or otherwise degrade when placed into these materials. Additionally, some semiconductor nanocrystals, such as PbS, may be very reactive and cannot be dispersed in many thin films by known techniques.

### SUMMARY OF THE INVENTION

In an embodiment, the present invention provides a micronized semiconductor nanocrystal complex comprising a plurality of semiconductor nanocrystals dispersed in a first matrix material, wherein the first matrix material is micronized. The micronized semiconductor nanocrystal complex can further comprise a second matrix material, wherein the first matrix material is dispersed in the second matrix material.

In another embodiment, the present invention provides a micronized semiconductor nanocrystal complex comprising a base matrix material comprising a plurality of first semiconductor nanocrystals dispersed in a first matrix material and a plurality of second, different semiconductor nanocrystals dispersed in a second matrix material, wherein both the first and second matrix materials are micronized.

In another embodiment, the present invention provides a device comprising a light emitting diode and a micronized semiconductor nanocrystal complex. The micronized semiconductor nanocrystal complex comprises a plurality of semiconductor nanocrystals in a first matrix material, wherein the first matrix material is micronized and a second matrix material wherein the first matrix material is dispersed in the second matrix material. The micronized semiconductor nanocrystal complex is placed on the surface of the light emitting diode.

The micronized semiconductor nanocrystal complexes of the present invention have many advantages over traditional semiconductor nanocrystals. One advantage of micronized semiconductor nanocrystals complexes of the present invention is that the plurality of semiconductor nanocrystals in the first matrix material become resistant to quenching. Furthermore, a plurality of semiconductor nanocrystals placed in a micronized first matrix material may be hermetically sealed from the environment, which can be important because many semiconductor nanocrystals contain Pb, Cd and other heavy metal elements that may be harmful to the environment. Additionally, micronizing a first matrix material containing a plurality of semiconductor nanocrystal allows such semiconductor nanocrystals to be dispersed in various second matrix materials, in which traditional semiconductor nanocrystals could not be dispersed because of incompatibility with the second matrix material.

Specifically with respect to PbS core nanocrystals, such semiconductor nanocrystals have been found to be incompatible with varnishes, linseed oil, tongue-oil, and many ultraviolet (UV) curable inks. However, placing PbS nanocrystals in a matrix material and micronizing this matrix material allows the PbS nanocrystals to be placed in these same varnishes, linseed oil, tongue oil, and many UV curable epoxies. This feature of the micronized semiconductor nanocrystal complexes of the present invention allows them to be used in or comprise various inks, paints and dyes. Whereas traditional methods of placing PbS nanocrystals into many UV curable inks have been found to quench the PbS nanocrystals, PbS nanocrystals placed in a matrix material, such as a polymer, according to the present invention, are stable when dispersed in the same UV curable inks.

Micronized semiconductor nanocrystal complexes of the present invention may also be used as a tracing device. For example, infrared emitting PbS nanocrystals may be embedded in a first matrix material and micronized. The resulting micronized semiconductor nanocrystal complex may be undetectable to the naked eye. Thus, the resulting complex could be sprinkled on a surface and used to detect the presence of an intruder through the use of an excitation source and an infra red detector. The size of the micronized particles may be controlled by traditional methods of manufacturing such as wet milling, jet milling and grinding such that footprints or fingerprints may be detected using an infrared detector and an excitation source.

The ability to control the size of micronized nanocrystal complexes of the present invention through known grinding, milling and sieving techniques, allow the micronized particles to be used to trace the flow of a liquid, such as water. Whereas most filters are unable to filter semiconductor nanocrystals in a liquid, micronized semiconductor nanocrystal complexes of the present invention allow the size of the particles to be controlled to ensure that the majority of the particles are trapped by a filtration system.

Furthermore, the ability to control the size of micronized semiconductor nanocrystal complexes of the present invention also has advantages with respect to lighting applications. Traditional semiconductor nanocrystals when uniformly dispersed throughout a solution or matrix do not scatter light due to their extremely small size. Some lighting applications using phosphors require scattering to ensure an optimized absorbance and optimized white light emission. Micronized semiconductor nanocrystal complexes, according to the present invention, can ensure isotropic light emission. Additionally, electroluminescent displays may be made by using a transparent conductor (such as ITO), a bottom electrode of metal (conductor) and micronized semiconductor nanocrystal complexes of the present invention. In these electroluminescent displays, the micronized semiconductor nanocrystal complexes may be dispersed in the transparent conductor.

Micronized semiconductor nanocrystal complexes of the present invention may further be used in personal care, drug products or cosmetics. An advantage of using a micronized semiconductor nanocrystal complex instead of only a semiconductor nanocrystal, is that semiconductor nanocrystals in a micronized first matrix material, such as a polymer, are less likely to absorb into the skin and/or leech into the environment than traditional semiconductor nanocrystals.

In addition to its advantages in the above-described applications, micronized semiconductor nanocrystal complexes of the present invention also allow the percentage of semiconductor nanocrystrals in the final complex and the size of the end products to be controlled. For example, micronized semiconductor nanocrystal complexes of the present invention may be accompanied with a dissolving solvent. Any user may then easily dissolve the micronized semiconductor nanocrystal complex in the solvent, add additional amounts of a first matrix material or additional semiconductor-nanocrystals, and determine the desired final concentration of semiconductor nanocrystals in the first matrix material. Thus, a user with little or no experience in semiconductor nanocrystal synthesis may be able to control the desired concentration of semiconductor nanocrystals in a matrix material. Additionally, due to their small size, a user may easily dissolve a micronized semiconductor nanocrystal complex and spin coat or paint the resulting solution directly onto any desired substrate.

### BRIEF DESCRIPTION OF THE DRAWINGS

FIG. 1 is a schematic illustration of a semiconductor nanocrystal of a micronized semiconductor nanocrystal complex of the present invention.

FIG. 2 is a flow chart illustrating an exemplary method of making a semiconductor nanocrystal complex according to the present invention.

FIG. 3 is a flow chart illustrating an exemplary method of making a semiconductor nanocrystal complex according to the present invention.

FIG. 4 is a flow chart illustrating an exemplary method of a making a semiconductor nanocrystal complex according to the present invention.

### DETAILED DESCRIPTION OF THE INVENTION

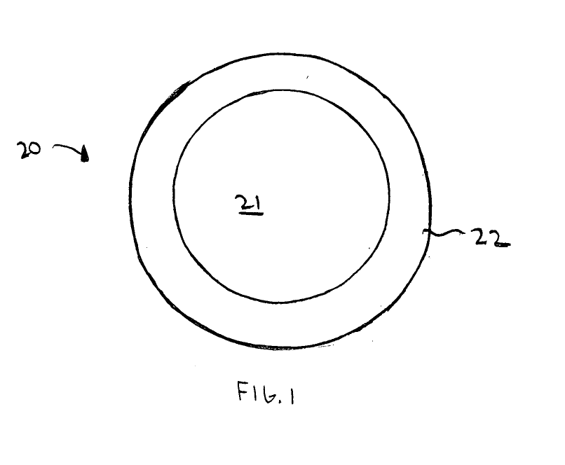

The present invention provides a micronized semiconductor nanocrystal complex comprising a plurality of semiconductor nanocrystals dispersed in a matrix material, wherein the matrix material is micronized. As is generally known in the art, semiconductor nanocrystals are spherical nanoscale crystalline materials (although oblate and oblique spheroids can be grown as well as rods and other shapes) having a diameter between 1 nm and 20 nm typically but not exclusively comprising II-VI, III-V, and IV-VI binary semiconductors. Referring to FIG. 1, a semiconductor nanocrystal 20 according to the present invention includes a core 21 of a first semiconductor that has a selected composition and diameter that enables light emission at a predetermined wavelength and optionally one or more shells 22 of a second semiconductor preferably having a bulk bandgap greater than that of the first semiconductor of core 21. Optional one or more shells 22 is preferably between 0.1 nm and 10 nm thick. Non-limiting examples of semiconductor materials that may comprise core 21 include ZnS, ZnSe, ZnTe, CdS, CdSe, CdTe, HgS, HgSe, HgTe (II-VI materials), PbS, PbSe, PbTe (IV-VI materials), AlN, AlP, AlAs, AlSb, GaN, GaP, GaAs, GaSb, InN, InP, InAs, InSb (III-V materials) and alloys and combinations thereof. Non-limiting examples of materials that may comprise the one or more shells 22 include CdSe, CdS, CdTe, ZnS, ZnSe, ZnTe, HgS, HgSe, HgTe, InP, InAs, InSb, InN, GaN, GaP, GaAs, GaSb, PbSe, PbS, PbTe and alloys and combinations thereof.

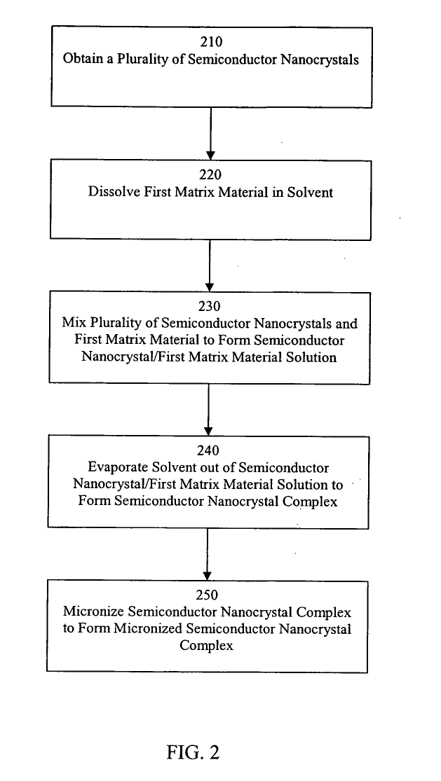

FIG. 2 depicts a flow chart illustrating an exemplary method of making a micronized semiconductor nanocrystal complex according to an embodiment of the present invention. In step 210, a plurality of semiconductor nanocrystals is obtained, for example, by preparing a plurality of semiconductor nanocrystals using any known method or purchasing a plurality of semiconductor nanocrystals (Evident Technologies, Troy, N.Y.). The plurality of semiconductor nanocrystals can be a plurality of the same semiconductor nanocrystals or two or more different semiconductor nanocrystals. For example, the two or more different semiconductor nanocrystals may include semiconductor nanocrystals comprising different cores and/or shells or semiconductor nanocrystals that luminesce at different wavelengths. The plurality of semiconductor nanocrystals may be dissolved in any appropriate solvent, such as, for example, toluene to form a semiconductor nanocrystal solution or may be obtained already in solution.

In step 220, a first matrix material is dissolved in the same type of solvent as is the plurality of semiconductor nanocrystals to form a first matrix material solution. Non-limiting examples of matrix materials that are soluble in toluene, a common solvent used in the preparation of semiconductor nanocrystals, include polystyrene, polymethylmethacrylate, polyacrylate, poly(n-butyl methacrylate and derivatives. The first matrix material may be dissolved in the solvent by heating the solvent at approximately 110° C., for example, until the first matrix material is dissolved to form a first matrix material solution. It is appreciated that the temperature indicated for dissolving the first matrix material is only exemplary and the proper temperature and time to dissolve may depend on the initial size of the first matrix material, the temperature, as well as the type of first matrix material used.

In step 230, the semiconductor nanocrystal solution obtained in step 210 is added to the first matrix material solution obtained in step 220 to form a semiconductor nanocrystal/first matrix material solution. In embodiments where the plurality of semiconductor nanocrystals is a plurality of two or more different semiconductor nanocrystals, the semiconductor nanocrystal solution comprising the plurality of two or more different semiconductor nanocrystals can similarly be added to first matrix material solution to form a semiconductor nanocrystal/first matrix material solution. Alternatively, each of the plurality of two or more different semiconductor nanocrystals may be separately dissolved a solvent and then each of the resultant semiconductor nanocrystal solutions can be added to the first matrix material solution to form a semiconductor nanocrystal/first matrix material solution. This solution is then mixed by simply stirring the solution, for example. Because the plurality of semiconductor nanocrystals and the first matrix material are both soluble in the same solvent, the addition of the semiconductor nanocrystal solution to the first matrix material solution allows the plurality of semiconductor nanocrystals to mix homogeneously with the first matrix material.

In step 240, the solvent is evaporated out of the semiconductor nanocrystal/first matrix material solution leaving a solid semiconductor nanocrystal complex comprising the plurality of semiconductor nanocrystals in the first matrix material. Initially, the solvent may be evaporated by heating the semiconductor nanocrystal/first matrix material solution to 110° C., for example. The solution may then be poured in a tray and placed in a fume hood to evaporate all remaining solvent leaving a solid semiconductor nanocrystal complex.

In step 250, the semiconductor nanocrystal complex is micronized. Initially, the semiconductor nanocrystal complex can be blended to reduce the size of the plurality semiconductor nanocrystals and to make it easier to micronize the particles. The desired size of the particles may vary depending on the application. The particles may be micronized from anywhere between 0.5 microns to 100 microns. The micronization may take place by known micronization techniques, such as, for example, blending, grinding, milling, and jet milling.

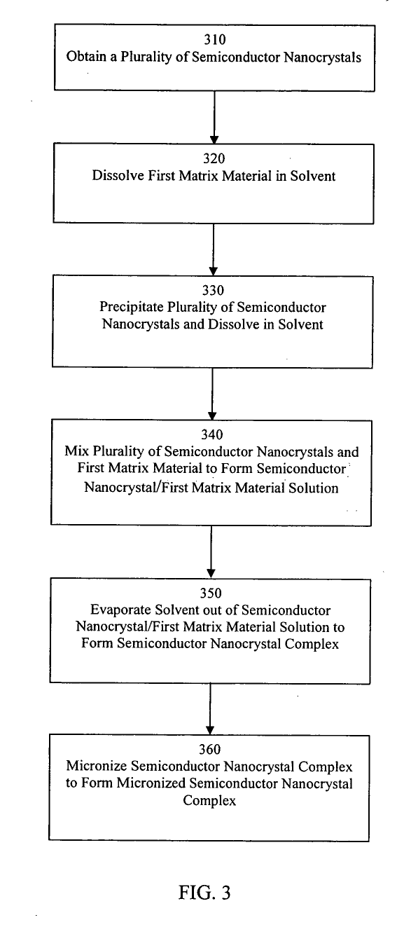

FIG. 3 represents another exemplary method of making a micronized semiconductor nanocrystal complex according to the present invention. In step 310, a plurality of semiconductor nanocrystals is obtained by preparing a plurality of semiconductor nanocrystals using any known method or purchasing a plurality of semiconductor nanocrystals (Evident Technologies, Troy, N.Y.). The plurality of semiconductor nanocrystals can be a plurality of the same semiconductor nanocrystals or two or more different semiconductor nanocrystals. The plurality of semiconductor nanocrystals may be dissolved in any appropriate solvent, such as, for example, toluene to form a semiconductor nanocrystal solution or may be obtained already in solution.

In step 320, a first matrix material is dissolved in a solvent that is different than the type of solvent in which the plurality of semiconductor nanocrystals is dissolved because, for example, the first matrix material is insoluble in the type of solvent in which the plurality of semiconductor nanocrystals is dissolved. As such, a solvent is chosen that will dissolve both the plurality of semiconductor nanocrystals in solution and the first matrix material. Non-limiting examples of solvents that have been found to dissolve semiconductor nanocrystals and matrix materials include anisole, chloroform, hexane, and trichloroethylene. Examples of matrix materials that can be dissolved in such various solvents include polymethylmethacrylate and polyacerlates, poly(n-butyl methacrylate and derivatives. The first matrix material can be dissolved in the solvent by heating the solvent to approximately 110° C., for example, until the first matrix material is dissolved to form a first matrix material solution. It is appreciated that the temperature indicated for dissolving the first matrix material is only exemplary and the proper temperature and time to dissolve may depend on the initial size of the first matrix material, the temperature, as well as the type of first matrix material used.

In step 330, the plurality of semiconductor nanocrystals in the semiconductor nanocrystal solution obtained in step 310 is precipitated out of solution. The plurality of semiconductor nanocrystals may be precipitated out of solution by adding methanol to the solution. Once the majority of the plurality of semiconductor nanocrystals have been precipitated out of solution, the solution can be centrifuged to collect the plurality of semiconductor nanocrystals. The plurality of semiconductor nanocrystals are then dissolved in the same type of solvent in which the first matrix material has been dissolved to again form a semiconductor nanocrystal solution.

In step 340, the semiconductor nanocrystal solution obtained in step 330 is added to the first matrix material solution to form a semiconductor nanocrystal/first matrix material solution. In embodiments where the plurality of semiconductor nanocrystals is a plurality of two or more different semiconductor nanocrystals, the semiconductor nanocrystal solution comprising the plurality of two or more different semiconductor nanocrystals can similarly be added to first matrix material solution to form a semiconductor nanocrystal/first matrix material solution. Alternatively, each of the plurality of two or more different semiconductor nanocrystals may be separately dissolved a solvent and then each of the resultant semiconductor nanocrystal solutions can be added to the first matrix material solution to form a semiconductor nanocrystal/first matrix material solution. This solution is then mixed by simply stirring the solution, for example. Because the plurality of semiconductor nanocrystals and the first matrix material are both able to dissolve in the same solvent, the addition of the semiconductor nanocrystal solution to the first matrix material solution allows for the plurality of semiconductor nanocrystals to mix homogeneously with the first matrix material.

In step 350, the solvent is evaporated out of the solution leaving a solid semiconductor nanocrystal complex comprising a plurality of semiconductor nanocrystals in the first matrix material. Initially, the solvent may be evaporated by heating the semiconductor nanocrystal/first matrix material solution to 110° C., for example. This solution may then be poured in a tray and placed in a fume hood and to evaporate all remaining solvent leaving a solid semiconductor nanocrystal complex.

In step 360, the semiconductor nanocrystal complex is micronized. Initially, the semiconductor nanocrystal complex can be blended to reduce the size of the semiconductor nanocrystals and make it easier to micronize the particles. The desired size of the particles may vary depending on the application. It has been found that the particles may be micronized from anywhere between 0.5 microns to 100 microns. The micronization may take place by known micronization techniques.

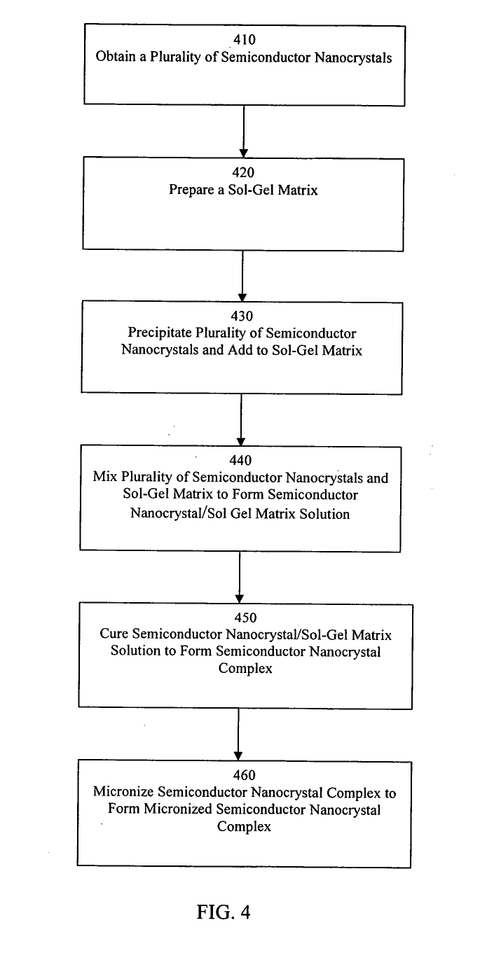

FIG. 4 represents an exemplary method of making a micronized semiconductor nanocrystal complex according to the present invention, wherein the first matrix material is a sol-gel matrix. It is appreciated that although the below described procedure is described with respect to the addition of one type of semiconductor nanocrystal more than one type of semiconductor nanocrystal may be used.

In step 410, a plurality of semiconductor nanocrystals is obtained as described above. The plurality of semiconductor nanocrystals obtained may be dissolved in toluene to form a semiconductor nanocrystal solution or may be obtained already in solution.

In step 420, the sol-gel matrix material is prepared. It is appreciated that there are many known methods of making a sol-gel matrix that may be used for the purpose of the present invention, such as, for example, combining silica with various other materials into a solution.

In step 430, the plurality of semiconductor nanocrystals obtained in step 410 is precipitated out of solution and added to the sol-gel matrix prepared in step 420. The plurality of semiconductor nanocrystals may be precipitated out of the solution by adding methanol to the solution. Once the majority of the plurality of semiconductor nanocrystals has been precipitated out of solution, the solution can be centrifuged to collect the plurality of semiconductor nanocrystals. The plurality of semiconductor nanocrystals can then be added to the sol-gel matrix.

In step 440, the plurality of semiconductor nanocrystals is mixed, such as by sonication, with the sol-gel matrix to form a homogenous semiconductor nanocrystal/sol-gel matrix solution.

In step 450, the semiconductor nanocrystal/sol-gel matrix solution is poured onto a surface, such as a polycarbonate sheet, and cured to form a semiconductor nanocrystal complex. The curing can be accomplished by any known method in the art such as using a curing lamp (1=360 nm).

In step 450, the semiconductor nanocyrstal complex from step 450 is micronized. Initially, the semiconductor nanocrystal complex can be blended to reduce the size of the semiconductor nanocrystals and make it easier to micronize the particles. The desired size of the particles may vary depending on the application. It has been found that the particles may be micronized from anywhere between 0.5 microns to 100 microns. The micronization may take place by known micronization techniques.

In any of the embodiments of the present invention, the first matrix material of the micronized semiconductor nanocrystal complex can be dispersed into a second matrix material and any additional number of matrix materials. Alternatively, the micronized semiconductor nanocrystal complex can comprise a plurality of matrix materials, each of the matrix materials including a plurality of different semiconductor nanocrystals, wherein each of the material materials is micronized. Each of the plurality of matrix materials can be contained within another matrix material. For example, in one embodiment, a micronized semiconductor nanocrystal complex comprises a base matrix material comprising a plurality of first semiconductor nanocrystals dispersed in a first matrix material and a plurality of second, different semiconductor nanocrystals dispersed in a second matrix material, wherein both the first and second matrix materials are micronized.

Micronized semiconductor nanocrystal complexes of the present invention have many applications. For example, such complexes can be used in or comprise inks, paints, and dyes. For example, in embodiments where a micronized semiconductor nanocrystal complex comprises a plurality of semiconductor nanocrystals dispersed in a first matrix material, the first matrix material can be placed directly onto a desired substrate using any known method of printing such as, for example, ink jet printing, gravure rolling, offset printing, or silk screening. Alternatively, in embodiments where a micronized semiconductor nanocrystal complex comprises a plurality of semiconductor nanocrystals dispersed in a first matrix material and the first matrix material is dispersed in a second matrix material, the second matrix material can be a known ink, paint, or dye. Such a micronized semiconductor nanocrystal complex can then by placed on a substrate using known methods of placing inks, paints, and dyes onto substrates. When mixing micronized semiconductor nanocrystals with an ink, paint, or dye, factors to be considered include the viscosity of the ink, paint or dye, the desired color of the resulting material, the size of the micronized particles, as well as the substrate.

The resulting micronized semiconductor nanocrystal complexes used in or comprising inks, paints or dyes have uses in many security applications. For example, micronized semiconductor nanocrystal complexes comprising a plurality of semiconductor nanocrystals emitting in the infra-red range can be placed onto ticket stubs, currency, or other important documents and used for authentication. Additionally, micronized semiconductor nanocrystal complexes comprising a plurality of CdSe nanocrystals emitting at various red, green and blue can be mixed together to make a visibly emitting spectral bar code that can be detected with a spectral bar code reader. It is appreciated that more than one type of micronized semiconductor nanocrystal complex may comprise or be used in the same ink, paint, or dye. Additionally, it is appreciated that two types of a plurality of semiconductor nanocrystals in a single micronized first matrix material of a micronized semiconductor nanocrystal complex may comprise or be used in an ink, paint or dye.

In an exemplary embodiment, an ink, paint or dye is made using a semiconductor nanocrystal complex comprising PbS nanocrystals in a polystyrene matrix material that is micronized to a size less than 1 micron. This micronized semiconductor nanocrystal complex is used as a ink, paint, or dye and is printed directly onto a substrate using an ink jet printer. In another exemplary embodiment, an ink is made using a micronized semiconductor nanocrystal complex comprising PbS nanocrystals in a polystyrene matrix material that is micronized and placed into a UV curable ink.

In another exemplary embodiment, a plurality of PbS semiconductor nanocrystals are dispersed in a first matrix material of polystyrene and then this first matrix material is micronized. This micronized first matrix material is then dispersed in a second matrix material of polyurethane and mixed to form a micronized semiconductor nanocrystal complex. This semiconductor nanocrystal complex is then painted onto a substrate.

Micronized semiconductor nanocrystal complexes of the present invention can also be used in lighting applications. Traditional semiconductor nanocrystals when uniformly dispersed throughout a solution or matrix do not scatter light due to their extremely small size. Some lighting applications using phosphors require scattering to ensure an optimized absorbance and optimized white light emission. Micronized semiconductor nanocrystal complexes of the present invention can be used to create isotropic light emission. In this instance, the first matrix material of the micronized semiconductor nanocrystal complex may be, for example, silica sol-gel that does not degrade under blue or UV excitation. Although, some optical epoxies do not degrade under blue or UV excitation, such optical epoxies have been shown to be incompatible with semiconductor nanocrystals. Micronized semiconductor nanocrystal complexes of the present invention can be placed into or comprise optical epoxies to scatter light and be excitable by blue or UV excitation.

In addition to being able to be used as a phosphor, micronized semiconductor nanocrystal complexes of the present invention may also be used in the production of light emitting diodes. In such embodiments, the micronized semiconductor nanocrystal complex comprises a plurality of semiconductor nanocrystals dispersed in a first matrix material that is a silica sol-gel, wherein the first matrix material is micronized and the first matrix material is dispersed in a second matrix material that may be an optical epoxy or silicone binder to form a light emitting diode that emits at a desired wavelength. Visibly emitting semiconductor nanocrystals such as, for example, CdS, CdSe, CdTe, InP, InN, ZnSe, may be used in the micronized semiconductor nanocrystal complexes in this embodiment. Presently, white light emitting diodes typically are excited by a 460-480 nm InGaN emitter with a cerium doped yttrium aluminum garnet (YAG) phosphor placed on top of the light emitting diodes. Often, light emitting diodes made by this technique are too blue, especially for general illumination. Micronized semiconductor nanocrystal complexes of the present invention can be used in addition to or instead of YAG phosphors to create a light with more red emission. For example, in addition to the YAG phosphors, red emitting CdS nanocrystals dispersed in a first matrix material that is micronized may be added to the optical epoxy containing YAG. It is appreciated that the disclosed use of micronized semiconductor nanocrystal complexes of the present invention can work not only for light emitting diodes but also in plasma displays, fluorescent lighting, or with any other blue or ultra violet source emitter. It is further appreciated that red, green and blue micronized semiconductor nanocrystal complexes of the present invention or other combinations of wavelengths can be placed on top of to a ultraviolet emitting diode to create a white light emitting diode.

In an embodiment, an exemplary light emitting diode is created as follows. A micronized semiconductor nanocrystal complex is prepared that comprises a plurality of semiconductor nanocrystals dispersed in a first matrix material, wherein the first matrix material is micronized. Preferably, the first matrix material is a silica sol-gel because it does not degrade under blue or UV excitation. The first matrix material is dispersed into a second matrix material of optical epoxy/binder. The resulting micronized semiconductor nanocrystal complex is found to scatter light and is excited with both a blue and ultraviolet excitation source without degrading. The resultant micronized semiconductor nanocrystal complex can be applied to the surface of a light emitting diode by spin coating, dip coating, spraying or through the use of a syringe for example. Additionally, the micronized semiconductor nanocrystal complex can comprise a plurality of semiconductor nanocrystals that luminesce at different wavelengths that is placed in the same second matrix material or the micronized semiconductor nanocrystal complex can comprise a plurality of semiconductor nanocrystals that luminesce at the same wavelength dispersed in a first matrix material and a plurality of semiconductor nanocrystals that luminesce at another wavelength dispersed in a second matrix material, wherein the first and second matrix materials are added to a third matrix material.

Another application for micronized semiconductor nanocrystal complexes of the present invention is in electroluminescent displays. Electroluminescent displays often use micronized phosphors sandwiched between a transparent conductor, such as ITO film, and a metal bottom electrode, wherein an electric current is applied and a light characteristic of the phosphor is emitted. Micronized semiconductor nanocrystal complexes of the present invention may be used as phosphors in these applications. In such embodiments, the first matrix material of the micronized semiconductor nanocrystal complex may be a conducting polymer such as, for example, polythiophene, polyaniline, polyacetylene, polypyrrole, or poly(2-methoxy-5-(2′-ethyl-nexyloxy)-paraphenylene vinylene. In such embodiments, a micronized semiconductor nanocrystal complex may be dispersed in place of or in addition to the phosphors in the production of electro-luminescent devices.

A further application for micronized semiconductor nanocrystal complexes of the present invention is in personal care or drug products. The properties of micronized semiconductor nanocrystals complexes of the present invention that may be taken advantage of when used in conjunction with a personal care product include fluorescence (as a pigment) and the micronized semiconductor nanocrystal's ability to optically diffuse light (for example, to minimize wrinkles). Exemplary first matrix materials of micronized semiconductor nanocrystal complexes of the present invention that may be micronized and used for these applications include, but are not limited to, polymers and silica sol-gels. Micronized semiconductor nanocrystal complexes, according to this embodiment, can include first matrix materials suspended in second matrix materials including, for example, alcohol based products, antiseptics, astringents, emulsions (including water and oil, oil and wax, wax and water, water and silicone), silicone, and oil based ointments. Many personal care and drug products are currently made using these second matrix materials including, but not limited to, hair conditioner, moisturizer, sun tan lotion, lipstick, hair gel, etc. A plurality of semiconductor nanocrystals dispersed in a micronized first matrix materials of micronized semiconductor nanocrystal complexes of the present invention, may be easily mixed into these second matrix materials, suspended and applied in the same manner as the products are currently applied.

Micronized semiconductor nanocrystal complexes of the present invention can also be used directly as taggants or tagging agents for liquid flow, to authenticate a liquid, or to detect an object or person. These applications take advantage of a micronized semiconductor nanocrystal complex's robustness, fluorescence and ability to resist quenching. Specifically, micronized semiconductor nanocrystal complexes of the present invention can be dispersed in water. In such embodiments, a plurality of semiconductor nanocrystals of a micronized semiconductor nanocrystal complex of the present invention may be suspended in a first matrix material comprising a polymer and placed directly in water. The flow of the water may then be traced by detecting the fluorescence of the particles during the flow process. Micronized semiconductor nanocrystal complexes of the present invention can be used as a tracer in gasoline or other liquids. The luminescent properties of a plurality of semiconductor nanocrystals in a first matrix material that is a silica sol-gel, for example can be used to authenticate the gasoline or other liquid. With respect to using micronized semiconductor nanocrystal complexes of the present invention to detect an object or person, in such embodiments micronized semiconductor nanocrystal complexes can comprise a plurality of infra red PbS semiconductor nanocrystals embedded in a first matrix material and micronized. The resulting micronized semiconductor nanocrystal complex may be undetectable to the naked eye. Thus, the resulting complex could be sprinkled on a surface and used to detect the presence of an intruder through the use of an infra red detector. The size of the micronized particles may be controlled by traditional methods of manufacturing and footprints or fingerprints may be detected on the surface using the infra red detector.

### EXAMPLES

### Example 1

The following example describes a process for preparing a micronized semiconductor nanocrystal complex comprising a plurality of PbS semiconductor nanocrystals in a first matrix material that is polystyrene, wherein the polystyrene is micronized.

PbS semiconductor nanocrystals are purchased in toluene (Evident Technologies, Troy, N.Y.). 99 g of polystyrene is dissolved in 1.0 L of toluene at 110.6° C. (boiling). After the polystyrene is dissolved, 1.0 g of PbS semiconductor nanocrystals are added to the solution and mixed. Next, the toluene is evaporated by heating the solution to 110.6° C. until the total volume is reduced to approximately 500 mL. The solution is then poured into a 9×13 inch Pyrex tray, and placed in a fume hood overnight to allow for most of the solvent to evaporate. The remaining solvent is removed using a vacuum oven (50° C.) resulting in formation of a polymer/semiconductor nanocrystal solid. This resulting solid is then be processed in a blender and micronized to the desired size to form a micronized semiconductor nanocrystal complex.

### Example 2

The following example describes a process for preparing a micronized semiconductor nanocrystal complex comprising a plurality of two different semiconductor nanocrystals (PbS and CdSe/ZnS nanocrystals) dispersed in a first matrix material that is polystrene.

PbS and CdSe/ZnS nanocrystals are purchased in toluene (Evident Technologies, Troy, N.Y.). 99 g of polystyrene are dissolved in 1.0 L of toluene at 110.6° C. (boiling). After the polystyrene is dissolved, 0.5 g of PbS semiconductor nanocrystals and 0.5 g of CdSe/ZnS nanocrystals are added to the solution and mixed. Next, the toluene is evaporated by heating the solution to 110.6° C. until the total volume is reduced to approximately 500 mL. The solution is then be poured into a 9×13 inch Pyrex tray, and placed in a fume hood overnight to allow most of the solvent to evaporate. The remaining solvent is removed using a vacuum oven (50° C.) resulting in formation of a polymer/semiconductor nanocrystal solid. This resulting solid is then processed in a blender and micronized to the desired size to form a micronized semiconductor nanocrystal complex.

### Example 3

The following example describes a process for preparing a micronized semiconductor nanocrystal complex comprising a plurality of semiconductor nanocrystals dispersed in a first matrix material that is a sol-gel matrix.

CdSe/ZnS nanocrystals are purchased in toluene (Evident Technologies, Troy, N.Y.). A sol-gel material is prepared by combining 1.2 g of colloidal silica (Highlink OG 108-32) with 0.5 g of an amine modified acrylate oligomer (Sartomer CN371) and 0.1 g of 1-hydroxycyclohexylphenyl ketone. The solution is sonicated until the solution is clear. While that solution is being prepared, 17 mg of CdSe/ZnS nanocrystals are precipitated from toluene by adding methanol. 1.7 mL of the sol-gel solution is added to the precipitated CdSe/ZnS nanocrystals, and the mixture is sonicated until forming a homogeneous solution. Under a nitrogen atmosphere (glove-bag), the solution is applied on the surface of a polycarbonate sheet, and the solution is cured using a curing lamp (1=360 nm) for one minute. The cured film is removed from the glove-bag and peeled from the polycarbonate sheet. The cured film is processed in a blender and then micronized to form a micronized semiconductor nanocrystal complex.

The foregoing description and examples have been set forth merely to illustrate the invention and are not intended as being limiting. Each of the disclosed aspects and embodiments of the present invention may be considered individually or in combination with other aspects, embodiments, and variations of the invention. In addition, unless otherwise specified, none of the steps of the methods of the present invention are confined to any particular order of performance. Modifications of the disclosed embodiments incorporating the spirit and substance of the invention may occur to persons skilled in the art and such modifications are within the scope of the present invention. Furthermore, all references cited herein are incorporated by reference in their entirety. Moreover, it is appreciated, that although a number of problems and deficiencies may be identified herein, each embodiment may not solve each problem identified in the prior art. Additionally, to the extent a problem identified in the prior art or an advantage of the present invention is cured, solved, or lessened by the claimed invention, the solution to such problems or the advantage identified should not be read into the claimed invention.

We claim:

1. A micronized semiconductor nanocrystal complex comprising:
a plurality of semiconductor nanocrystals dispersed in a first matrix material, wherein the first matrix material is micronized.

2. The micronized semiconductor nanocrystal complex of claim 1, further comprising a second matrix material, wherein the first matrix material is dispersed in the second matrix material.

3. The micronized semiconductor nanocrystal complex of claim 1 wherein, the plurality of semiconductor nanocrystals comprises a PbS core.

4. The micronized semiconductor nanocrystal complex of claim 1, wherein the first matrix material is a polymer.

5. The micronized semiconductor nanocrystal complex of claim 1, wherein the first matrix material limits the diffusion rate of oxygen molecules to the surface of the plurality of semiconductor nanocrystals.

6. The micronized semiconductor nanocrystal complex of claim 2, wherein the second matrix material is an ink, a paint or a dye.

7. The micronized semiconductor nanocrystal complex of claim 2, wherein the second matrix material is an emulsion or an alcohol-based composition.

8. A method of detecting the photoluminescent properties of the plurality of
semiconductor nanocrystals of claim 1 comprising:
placing the micronized semiconductor nanocrystal complex of claim 1 on a substrate; and
detecting the photoluminescent properties of the plurality of semiconductor nanocrystals of claim 1.

9. The method of claim 8, wherein placing the micronized semiconductor nanocrystal complex of claim 1 on a substrate comprises painting the micronized semiconductor nanocrystal complex of claim 1 onto a substrate.

10. The micronized semiconductor nanocrystal complex of claim 2, wherein the second matrix material is an ultraviolet-curable epoxy.

11. The micronized semiconductor nanocrystal complex of claim 1, wherein the plurality of semiconductor nanocrystals is a plurality of two or more different semiconductor nanocrystals.

12. The micronized semiconductor nanocrystal complex of claim 11, wherein the plurality of two or more different semiconductor nanocrystals is a plurality of first semiconductor nanocrystals and a plurality of second, different semiconductor nanocrystals.

13. A micronized semiconductor nanocrystal complex comprising:
a base matrix material comprising:
a plurality of first semiconductor nanocrystals in a first matrix material;
a plurality of second, different semiconductor nanocrystals in a second matrix material, wherein the first and the second matrix materials are micronized.

14. A device comprising:
a light emitting diode; and
a micronized semiconductor nanocrystal complex comprising:
a plurality of semiconductor nanocrystals in a first matrix material,
wherein the first matrix material is micronized; and
a second matrix material, wherein the first matrix material is dispersed in the second matrix material, wherein the micronized semiconductor nanocrystal complex is placed on the surface of the light emitting diode.

15. The device of claim 14, wherein the first matrix material is a silica sol-gel.

16. The device of claim 14, wherein the second matrix material is an optical epoxy.

17. The device of claim 14, wherein the plurality of semiconductor nanocrystals is a plurality of two or more different semiconductor nanocrystals.

18. A method of making the micronized semiconductor nanocrystal complex of claim 1 comprising:
dissolving a first matrix material in a solvent to form a first matrix material solution;
dissolving a plurality of semiconductor nanocrystals in the same solvent to form a semiconductor nanocrystal solution;
mixing the first matrix material solution and the semiconductor nanocrystal solution to form a semiconductor nanocrystal-first matrix material solution;
evaporating the solvent from the semiconductor nanocrystal-first matrix material solution to form a solid semiconductor nanocrystal complex; and
micronizing the solid semiconductor nanocrystal complex to form a micronized semiconductor nanocrystal complex.

19. A method of making the micronized semiconductor nanocrystal complex of claim 2 comprising:
dissolving a first matrix material in a solvent to form a first matrix material solution;
dissolving a plurality of semiconductor nanocrystals in the same solvent to form a semiconductor nanocrystal solution;
mixing the first matrix material solution and the semiconductor nanocrystal solution to form a semiconductor nanocrystal-first matrix material solution;
evaporating the solvent from the semiconductor nanocrystal-first matrix material solution to form a solid semiconductor nanocrystal-first matrix material composite; and
micronizing the solid semiconductor nanocrystal-first matrix material composite to form a micronized semiconductor nanocrystal-first matrix material composite; and
dispersing the micronized semiconductor nanocrystal-first matrix material composite in a second matrix material to form a semiconductor nanocrystal complex.

20. A method of making the semiconductor nanocrystal complex of claim 12 comprising:
dissolving a first matrix material in a solvent to form a first matrix material solution;
dissolving a plurality of first semiconductor nanocrystals in the solvent and a plurality of second, different semiconductor nanocrystals in the solvent to form a semiconductor nanocrystal solution;
mixing the first matrix material solution and the semiconductor nanocrystal solution to form a semiconductor nanocrystal-first matrix material solution;
evaporating the solvent from the semiconductor nanocrystal-first matrix material solution to form a solid semiconductor nanocrystal complex; and
micronizing the solid semiconductor nanocrystal complex.

21. A method of making the semiconductor nanocrystal complex of claim 13 comprising:
adding a plurality of first semiconductor nanocrystals to a first matrix material;
micronizing the first matrix material;
adding a plurality of second, different semiconductor nanocrystals to a second matrix material;
micronizing the second matrix material; and
adding the micronized first matrix material and the micronized second matrix material to a base matrix material.
